(19) United States
(12) Patent Application Publication
(10) Pub. No.: US 2008/0006441 A1
(43) Pub. Date: Jan. 10, 2008

(54) Wiring board and semiconductor device excellent in folding endurance

(75) Inventors: Makoto Yamagata, Shinagawa-ku (JP); Hiroaki Kurihara, Shinagawa-ku (JP); Naoya Yasui, Shinagawa-ku (JP); Noriaki Iwata, Shinagawa-ku (JP)

Correspondence Address: THE WEBB LAW FIRM, P.C., 700 KOPPERS BUILDING, 436 SEVENTH AVENUE, PITTSBURGH, PA, 15219, US

(73) Assignee: Mitsui Mining & Smelting Co., Ltd., Shinagawa-ku (JP)

(21) Appl. No.: 11/825,039

(22) Filed: Jul. 3, 2007

(30) Foreign Application Priority Data
Jul. 6, 2006 (JP) 2006-186256

(51) Int. Cl. H05K 1/16

(52) U.S. Cl. 174/260

(57) ABSTRACT

A wiring board with folding endurance includes an insulating film and a copper-containing wiring pattern on a surface of the insulating film, and includes an insulating resin coating layer formed on the wiring pattern such that terminals are exposed. The wiring board has any of the constitutions (A), (B), (C) and (D) below. (A) The wiring pattern includes copper particles having a mean crystal particle diameter in the range of from 0.65 to 0.85 μm as determined by EBSP; not more than 1% of the volume of the wiring pattern is accounted for by copper crystal particles having a particle diameter of less than 1.0 μm as determined by EBSP; and copper crystal particles that are [100] oriented in the longitudinal direction of a lead of the wiring pattern account for from 10 to 20% of the volume of the wiring pattern as determined by EBSP. (B) The insulating film is formed of a polyimide film having a tensile strength within the range of from 450 to 600 MPa and a Young's modulus within the range of from 8500 to 9500 MPa. (C) The insulating film is formed of a polyimide film having a thickness of from 10 to 30 μm. (D) The insulating resin coating layer has a thickness of from 50 to 150% relative to the thickness of the insulating film.

### BACKGROUND OF THE INVENTION

1. Field of the Invention

The present invention relates to a wiring board and a semiconductor device excellent in folding endurance. More specifically, the present invention relates to a wiring board and a semiconductor device having the wiring board and a semiconductor chip mounted thereon, in which breakage of wire is prevented even if the semiconductor device is folded when installed into electronic equipment or even if the semiconductor device is subjected to repeated stress by vibration, etc. during use of the electronic equipment.

2. Description of the Related Art

Semiconductor chips are used for driving display apparatuses such as liquid crystal display apparatuses and PDP (Plasma Display Monitor Panel). Such a semiconductor chip is mounted on a wiring board produced by forming a wiring pattern on the surface of an insulating film and is installed in an electronic apparatus. It is necessary that the semiconductor chips are installed in an electronic apparatus with high density. It is therefore frequent that the semiconductor chips are mounted on a wiring board as described above and the wiring board is folded and installed in an electronic apparatus. For example, when the wiring board is connected in a folded condition to an external electronic part such as a panel with use of ACF (anisotropic conductive film), wire breakage occurs frequently at between an edge of the insulating resin protection film (e.g., solder resist) and an edge of ACF, or in the vicinity of the connection terminals.

Japanese Patent Application Laid-Open No. 2006-117977 discloses “a rolled copper foil excellent in folding endurance, wherein not less than 40% of the sectional area of the copper foil having been annealed after final rolling is accounted for by crystal particles penetrating both surfaces of the copper foil in the thickness direction. This patent document describes that the copper foil is useful in forming a wiring pattern of a wiring board that is folded for use, and the obtainable flexible printed wiring board has good folding endurance.

Rolled copper foils as described above, however, are high in price as compared with electrodeposited copper foils, so the use of rolled copper foils cannot cope with price lowering of electronic products such as liquid crystal display apparatuses.

In this respect, electrodeposited copper foils are lower in price than rolled copper foils, and thus electrodeposited copper foils are preferably used for cost lowering of electronic equipment.

For instance, Japanese Patent Application Laid-Open No. 8-335607 discloses an invention of a single layer TCP (Tape Carrier Package) in which a base film and a metal foil (usually electrodeposited copper foil) having a tensile strength after heat treatment of from 20 to 30 kgf/mm² and a flexural elastic modulus of from 3000 to 5000 kgf/mm², are laminated without an adhesive.

When a wiring board having a thin copper foil is folded for use as described above, the wiring board is continuously subjected to a variety of stresses such as a repeated bending stress, shearing stress, twisting stress, and others. Consequently, wire breakage tends to take place in the folded portion, near the ACF edge and in the vicinity of the connection terminals. In particular, wire breakage is more frequent when the wiring pattern has inner leads at pitches of less than 35 μm, because formation of such fine wiring pattern entails use of a thin electrodeposited copper foil.

As described above, reduction of wire width in a wiring pattern involves use of a thinner conductive metal layer. On the other hand, the obtainable wiring pattern should achieve high folding endurance. That is, recent high density wiring boards require characteristics that will lead to deteriorated folding endurance of the wiring pattern folded for use. In other words, high densification in the wiring boards and improvement of folding endurance of the wiring pattern are conflicting factors and will not be satisfied easily at the same time. Moreover, strong demand for cost lowering adds difficulty. Thus, the conventional art has been unable to produce wiring boards satisfying these conflicting requirements.

Japanese Patent Application Laid-Open No. 2005-153357 discloses an invention of a resin film with a metal foil. This patent document describes that the metal foil has a cross section in which 1 to 60% of an area extending from the shiny surface to half the thickness of the metal foil is accounted for by crystal particles having a crystal particle diameter of not less than 1.0 μm as determined by EBSD method (wherein the crystal particle diameter is determined based on a sum of particle diameters obtained by multiplying the diameter by the area ratio on the assumption that the particles are spherical). The invention disclosed in this Japanese Patent Application Laid-Open No. 2005-153357 involves measurement of over-time change in the surface of the copper foil by the EBSD method in a short time and determination of whether or not the copper foil is usable based on the surface state of the copper foil. Thus, the relationship between the crystal state of the copper foil itself and folding endurance is not described in this Japanese Patent Application Laid-Open No. 2005-153357.

### SUMMARY OF THE INVENTION

An object of the present invention is to provide a wiring board and a semiconductor device in which a wiring pattern is formed with very high fineness and the wiring pattern has excellent folding endurance.

The present invention is directed to a wiring board excellent in folding endurance in which a copper-containing wiring pattern is formed on at least one face of an insulating film and in which an insulating resin coating layer is formed on the wiring pattern such that terminals of the wiring pattern are exposed, wherein the wiring board has at least one constitution selected from the group consisting of (A), (B), (C) and (D) below:
(A) the wiring pattern comprises copper particles having a mean crystal particle diameter in the range of from 0.65 to 0.85 μm as determined by means of an electron back-scatter patterning (EBSP) analyzer; not more than 1% of the volume of the wiring pattern is accounted for by copper crystal particles having a particle diameter of less than 1.0 μm as determined by EBSP; and copper crystal particles that are [100] oriented in the longitudinal direction of a lead of the wiring pattern account for from 10 to 20% of the volume of the wiring pattern as determined by EBSP;
(B) the insulating film is formed of a polyimide film having a tensile strength within the range of from 450 to 600 MPa and a Young's modulus within the range of from 8500 to 9500 MPa;
(C) the insulating film is formed of a polyimide film having a thickness of from 10 to 30 μm; and
(D) the insulating resin coating layer formed on the wiring pattern has a thickness of from 50 to 150% relative to the thickness of the insulating film.

The wiring board of the present invention can be folded at a curvature radius of from 0.1 to 5.0 mm, preferably from 0.3 to 3.0 mm and at 90 to 180° without wire breakage.

A semiconductor device according to the present invention comprises the wiring board and an electronic part such as a semiconductor chip mounted on the wiring board.

As described above, a wiring board having a semiconductor chip for driving a display apparatus such as a liquid crystal display apparatus or PDP is frequently folded for use. On the other hand, as the semiconductor chips are highly integrated, the pitch width of a wiring pattern becomes extremely narrow in the wiring board on which the semiconductor chips are mounted. Hence, it is very difficult to keep high adhesion between the insulating film and the wiring pattern.

The wiring board according to the present invention can be folded for use without the wiring pattern being separated from the insulating film, and the wiring pattern is resistant to breakage during long-term use in a folded state. Specifically, in the wiring board of the present invention, the wiring pattern is formed of conductive copper crystal particles that are oriented in a specific manner and whereby the wiring pattern achieves increased folding endurance. In the invention, the insulating film as a base of the wiring pattern is a polyimide film having specific characteristics. Such polyimide film in combination with the wiring pattern having the above specific characteristics can provide superior folding endurance. The folding endurance of the wiring board is noticeably enhanced also by controlling the thickness of the insulating resin coating layer (solder resist layer or cover layer) protecting the surface of the wiring pattern.

In the invention, the crystallinity of copper constituting the wiring pattern is improved, and the insulating film as a base of the wiring pattern has improved characteristics. Moreover, the solder resist layer or the like protecting the wiring pattern has a controlled thickness. These improvements and control singly or in combination provide remarkably increased folding endurance of the wiring board. Two or more of these improvements and control in combination produce a far more superior effect than obtained by simple addition of effects by the individual improvements and control.

### BRIEF DESCRIPTION OF THE DRAWING

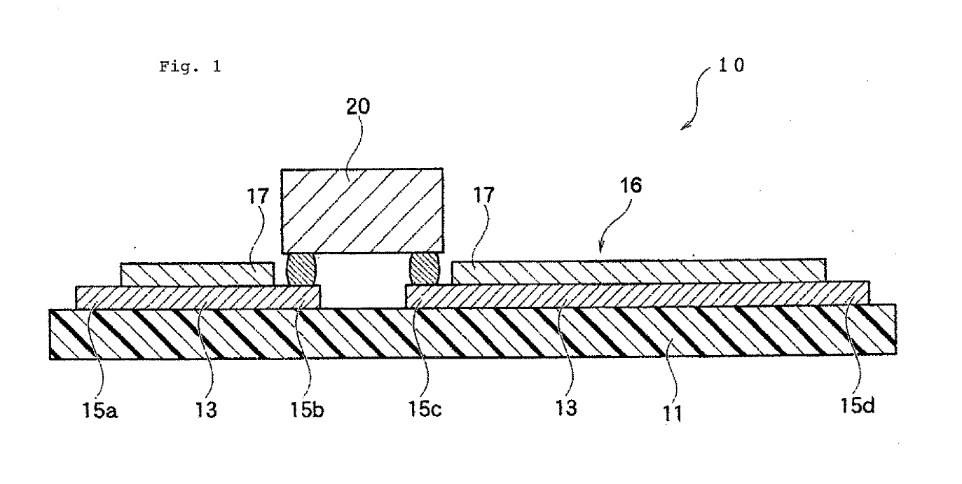

FIG. 1 is a drawing schematically illustrating an example of a cross section of a wiring board according to an embodiment of the present invention.
10: wiring board
11: insulating board (insulating film)
13: wiring pattern
15a: input side outer lead
15b: input side inner lead
15c: output side inner lead
15d: output side outer lead
16: folding portion
17: (insulating) resin coating layer (including a solder resist layer and a cover layer)
20: A semiconductor chip

### DESCRIPTION OF THE PREFERRED EMBODIMENT

Hereinbelow, a wiring board excellent in folding endurance of the present invention will be specifically discussed with reference to the drawing. FIG. 1 is a sectional view schematically illustrating an example of a wiring board of the present invention.

A wiring board 10 of the present invention, as shown in FIG. 1, has an insulating board 11 and a wiring pattern 13 formed on at least one face of the insulating board. This wiring pattern 13 has an input side outer lead 15a for inputting a signal from the outside into a semiconductor chip 20, an input side inner lead 15b for inputting the signal into the semiconductor chip 20, an output side inner lead 15c for outputting a signal transformed in the semiconductor chip 20, and an output side outer lead 15d for transmitting the transformed signal to an external apparatus. The input side outer lead 15a, input side inner lead 15b, output side inner lead 15c and output side outer lead 15d work as connection terminals for the semiconductor chip 20 or an external member, and thus these leads are exposed. The wiring pattern excluding the inner and outer leads is protected with a resin coating layer 17. Such resin coating layers 17 include solder resist layers and cover layers.

In the present invention, the wiring board 10 is usually flexible and has a folding portion 16 between, for example, the output side inner lead 15c and the output side outer lead 15d. In this folding portion 16, the wiring board 10 of the present invention is normally folded for use at from 90 to 180° and at a curvature radius R of from 0.1 to 5.0 mm. Although any special member is not used in the folding portion 16 in FIG. 1, a slit (not shown) or the like may be formed in the insulating board 11 corresponding to the folding portion 16 so that the wiring board of the invention can be folded easily. Alternatively, the solder resist layer forming the folding portion 16 may be formed of a resin having elasticity greater than other portions so that the wiring board of the invention can be folded more easily.

The present invention is highly useful when the wiring board has a wiring pattern 13 with a narrowest pitch width of normally 50 μm or less, suitably from 20 to 35 μm, and with a line bottom width of 25 μm or less, suitably from 10 to 20 μm.

For the improvement of folding endurance of the wiring board 10 of the present invention, first, characteristics of the wiring pattern 13 formed in the wiring board 10 are improved.

In other words, the wiring board according to the present invention has a constitution (A) as described below. The wiring pattern 13 formed in the wiring board 10 of the present invention is normally formed through the use of an electrodeposited copper foil. A generally used electrodeposited copper foil is produced by immersing a drum made of titanium or the like in an electrolyte containing copper to deposit crystal particles of copper in the radial direction when viewed from the center of the drum. Therefore, the copper crystal particles tend to grow perpendicular to the longitudinal direction of the electrodeposited copper foil obtained. Stress applied to the folding portion of the wiring pattern is applied in the thickness direction of the wiring pattern 13. Thus, when an electrodeposited copper foil which is an aggregate of copper crystal particles having grown substantially perpendicular to the longitudinal direction of the wiring board as mentioned above is used, grain boundaries of the copper crystal particles forming the electrodeposited copper foil are frequently broken by the stress applied in the thickness direction. Hence, the conventional electrodeposited copper foil has been unable to achieve sufficient folding endurance due to its crystal structure or particle shape. In particular, in recent wiring boards in which the pitch width of a wiring pattern is narrow and a sufficient wire width cannot be ensured, the improvement of folding endurance has limit because of the structure of the electrodeposited copper foil.

The wiring pattern formed in the wiring board of the present invention contains copper crystal particles having a relatively large particle diameter in an amount such that the relatively large copper crystal particles will account for a large proportion of the area of the wiring pattern, and contains copper crystal particles having a small particle diameter in an amount such that such small copper crystal particles will account for a certain proportion of the area of the wiring pattern. Moreover, a predetermined amount of the copper crystal particles are [100] oriented in the longitudinal direction of the wiring pattern. Consequently, the wiring board of the present invention has folding endurance against stress such as shearing stress applied in the longitudinal direction of the wiring pattern. Specifically, in the wiring pattern formed in the wiring board of the present invention, the mean particle diameter of the copper determined by EBSP is in the range of from 0.65 to 0.85 μm, preferably from 0.7 to 0.8 μm, and the volume percent occupied by the copper crystal particles having a particle diameter of less than 0.1 μm is limited to the range of 1.0% or less, preferably from 0.01 to 0.5%. Table 1 below shows the diameters and numbers of copper particles in the lead portion of the wiring board according to an embodiment of the present invention.

TABLE 1

| | Number of | Occupation |
|---|---|---|
| Particle diameter (μm) | particles | volume (%) |
| Less than 0.1 | 48 | 0.13 |
| 0.1 to less than 0.3 | 83 | 2.00 |
| 0.3 to less than 0.5 | 73 | 4.89 |
| 0.5 to less than 0.7 | 53 | 6.95 |
| 0.7 to less than 0.9 | 40 | 8.76 |
| 0.9 to less than 1.1 | 27 | 8.75 |
| 1.1 to less than 1.3 | 20 | 9.05 |
| 1.3 to less than 1.5 | 14 | 8.43 |
| 1.5 to less than 1.7 | 7 | 5.42 |
| 1.7 to less than 1.9 | 6 | 5.80 |
| 1.9 to less than 2.1 | 4 | 4.72 |
| 2.1 to less than 2.3 | 3 | 4.25 |
| 2.3 to less than 2.5 | 4 | 6.69 |
| 2.5 to less than 2.7 | 2 | 3.90 |
| 2.7 to less than 2.9 | 1 | 2.25 |
| 2.9 or more | 4 | 18.01 |

As shown in the table, the wiring pattern formed in the wiring board of the present invention contains copper crystal particles having a particle diameter of less than 0.1 μm. The volume percent occupied by such small particles in the wiring pattern is 1% or less, 0.5% or less in many cases.

As is apparent from FIG. 1 above, the mean crystal particle diameter of the copper particles forming the wiring pattern ranges from 0.65 to 0.85 μm, preferably from 0.7 to 0.8 μm. The particles with diameters deviating from the mean crystal particle diameter by not more than ±0.2 μm are normally from 20 to 45% in number, preferably from 25 to 40% in number based on the total number of particles. However, because the particle diameter of these particles is small as compared with the particles greater than the mean crystal particle diameter by more than 0.2 μm, the volume percent occupied by these particles in the wiring pattern is small, normally from 10 to 25 volume %, preferably from 15 to 22 volume %.

When the lead portion of the wiring pattern 13 formed in the wiring board of the present invention is analyzed by means of an electron back-scatter patterning (EBSP) analyzer, the copper crystal particles that are [100] oriented in the longitudinal direction of the wiring pattern are contained in an amount of from 10 to 20 volume %, preferably from 15 to 20 volume %. This electron back-scatter patterning (EBSP) analyzer irradiates a highly inclined sample with an electron beam and captures a channeling pattern formed by back-scattering on a screen to determine the crystal orientation at the point irradiated.

In the wiring board of the present invention, some of the copper crystal particles are [100] oriented along the longitudinal direction of the wiring pattern or the lead. Consequently, such copper crystal particles are substantially perpendicular to the copper crystal particles that tend to be arranged in the thickness direction of the wiring pattern or lead. The [100] oriented copper crystal particles join the copper crystal particles arranged in the thickness direction of the wiring pattern or lead, along the longitudinal direction of the wiring pattern or lead.

Shearing stress, bending stress, tortional stress or the like is applied to the wiring pattern or the lead when the wiring board is folded for use. These various stresses are responsible for the breakage of the wiring pattern or the lead. Thus, the breakage of the wiring pattern or the lead can be prevented if the [100] oriented copper crystal particles capable of resisting the shearing stress account for a predetermined volume percent. Moreover, the copper crystal particles constituting the wiring pattern or lead of the present invention have a large mean particle diameter, and small copper crystal particles having a particle diameter of less than 0.1 μm occupy only a limited volume of the wiring pattern or lead. Consequently, the copper crystal particles have a small number of grain boundaries at which the breakage can possibly take place.

The electrodeposited copper foil having the constitution as described above can be produced by, for example, depositing copper from a sulfuric acid-based copper electrolytic solution having a cyclic quaternary ammonium salt polymer such as diallyldimethylammonium chloride, an organic sulfonic acid such as 3-mercapto-1-propanesulfonic acid and a chloride ion. The concentration of the cyclic quaternary ammonium salt polymer in this case is normally in the range of from 1 to 50 ppm; the concentration of the organic sulfonic acid is normally in the range of from 3 to 50 ppm; the chloride ion concentration is normally in the range of from 5 to 50 ppm. Moreover, the copper concentration of this sulfuric acid-based copper electrolytic solution is normally in the range of from 50 to 120 g/liter; the free sulfuric acid concentration is in the range of from 60 to 250 g/liter. An electrodeposited copper foil for use in the present invention can be produced by depositing copper at a temperature of the sulfuric acid-based copper electrolytic solution in the range of from 20 to 60° C. and at a current density in the range of from 30 to 90 A/dm². Depositing copper under the above conditions from the above sulfuric acid-based copper electrolytic solution results in an electrodeposited copper foil containing a predetermined amount of copper crystal particles that have a large particle diameter and are [100] oriented in the longitudinal direction.

The electrodeposited copper foil formed in this manner has a deposition initiation face (S face) where the deposition of copper has initiated and a deposition completion face (M face) where the deposition of copper has completed. In the present invention, an insulating board such as a polyimide layer can be provided on any of the faces.

For example, when a polyimide layer is laminated on the M face of the electrodeposited copper foil, the polyimide layer is preferably laminated after the surface treatment of the electrodeposited copper foil. Examples of the surface treatments include roughening treatment in which copper fine particles are deposited and attached to, for example, the M face of the electrodeposited copper foil (nodule plating treatment) and then the copper fine particles attached to the face are fixed by coverplating treatment; rustproofing; and coupling agent treatment.

Of these, the roughening treatment is constituted by nodule plating treatment and coverplating treatment. The nodule plating treatment involves attaching copper fine particles on the M face of the electrodeposited copper foil from a plating solution having a low copper concentration of about from 5 to 20 g/liter and a free sulfuric acid concentration of about from 50 to 200 g/liter, normally at a solution temperature of from 15 to 40° C. and at a current density of from 10 to 50 A/dm², using an additive such as α-naphthoquinone, dextrin, glue or thiourea. The coverplating treatment immobilizes the copper fine particles attached as described above on the M face of the electrodeposited copper foil. Specifically, the deposition face of the electrodeposited copper foil having the copper fine particles thereon is covered with a copper plating layer which is formed from a plating solution having a copper concentration of about from 50 to 80 g/liter and a free sulfuric acid concentration of about from 50 to 150 g/liter, at a solution temperature of from 40 to 50° C. and at a current density of from 10 to 50 A/dm².

For instance, an insulating film is provided on at least one face of the electrodeposited copper foil formed as described above to form a laminate film; the electrodeposited copper foil layer of this board film is selectively etched to produce a wiring pattern.

In the present invention, for the improvement of folding endurance, the wiring board has a constitution (B) as described below. The insulating film has specific tensile strength and Young's modulus. A polyimide film is normally used as the insulating film constituting the wiring board of the present invention.

If the tensile strength of the polyimide film used as the insulating film of the present invention is within the range of from 450 to 600 MPa, preferably from 500 to 600 MPa, and the Young's modulus is within the range of from 8500 to 9500 MPa, preferably from 8800 to 9200 MPa, the breakage of the wiring pattern in the folding portion 16 can be effectively prevented in the wiring board of the present invention. In other words, the polyimide layer having the above tensile strength and Young's modulus can bear at least part of the bending stress applied to the wiring pattern in the folding portion 16. Thus, the stress on the wiring pattern in the folding portion 16 can be reduced, whereby the folding endurance of the wiring board of the present invention is improved.

In order that the polyimide layer as the insulating film has the above specific tensile strength and Young's modulus, the polyimide layer in the invention is formed from an aromatic tetracarboxylic dianhydride component which is preferably biphenyltetracarboxylic dianhydride or its derivative. In other words, the polyimide used as insulating film in the present invention can be obtained by the reaction of an aromatic diamine component with an aromatic tetracarboxylic dianhydride component. The aromatic tetracarboxylic dianhydride component used as raw material is preferably an acid anhydride having a plurality of aromatic rings, such as biphenyltetracarboxylic dianhydride, rather than an acid dianhydride having one aromatic ring (monocyclic acid dianhydride), such as pyromellitic dianhydride. Use of such polyaromatic ring-containing acid anhydride results in high tensile strength and Young's modulus of the obtainable polyimide. Therefore, where the insulating polyimide film needs high tensile strength and high Young's modulus, biphenyltetracarboxylic dianhydride and its derivatives are desirably used as a raw material aromatic tetracarboxylic dianhydride component.

A laminate (substrate film) of a copper layer and the polyimide film having the above tensile strength and Young's modulus as mentioned above can be produced, for example, by producing a polyimide film having the above characteristics in advance; forming a layer including a metal such as Ni and/or Cr on the surface of the polyimide film by means of, for example, sputtering; and then depositing Cu on the surface of the metal layer. The deposition of Cu can be carried out in a gas phase or liquid phase.

In the present invention, a board film can be formed also by laminating the polyimide film having the above tensile strength and Young's modulus as described above and a copper foil. Alternatively, a polyimide precursor capable of forming the polyimide as described above is cast and extended on the surface of a copper foil and then the precursor is heat cured to produce a substrate film. The heat curing temperature in this case is normally from 100 to 350° C., and the heat curing time is normally from 0.5 to 24 hours.

The polyimide, and board film composed of the polyimide and a copper foil can be produced according to the descriptions of, for example, Japanese Patent Application Laid-Open Nos. 2000-244063 and 2000-208563.

The wiring board of the present invention has a constitution (C): The insulating film is formed of a polyimide film and the thickness of the polyimide film is from 10 to 30 μm, preferably from 22 to 28 μm, and more preferably from 23 to 26 μm, whereby the folding endurance of the wiring board of the present invention is improved. In general, a flexible wiring board includes a polyimide film as insulating film which has a thickness of more than 30 μm. In contrast, the present invention employs a polyimide film thinner than the usual insulating polyimide film. As a result, bending of the polyimide film produces a reduced stress generated from the polyimide film itself. Consequently, the wiring board of the present invention shows high folding endurance.

Folding endurance test has shown that according to the constitution (C), the outer lead pattern has folding endurance 2 to 10 times larger than that obtained with a thick polyimide film, as determined using an MIT testing apparatus at a bending radius of 0.8 mm, a bending angle of ±135°, a bending speed of 175 rpm and a load of 100 gf/10 mm.

Furthermore, the wiring board of the present invention has a constitution (D) as described below. The thickness of the insulating resin coating layer 17 (solder resist layer or cover layer) formed so as to cover the wiring pattern formed by selectively etching the copper foil of the board film as described above is grater than usual. Consequently, the breakage of the wiring pattern in the folding portion 16 is prevented.

In the wiring board, flexible wiring board in particular according to the present invention, the input side outer lead 15a, input side inner lead 15b, output side inner lead 15c and output side outer lead 15d are connection terminals and are connected to the semiconductor chip 20 or external electronic parts. Therefore, the conductive metal of these outer and inner leads needs to be exposed, and portions other than these leads are generally covered with the insulating resin coating layer 17 for protecting the wiring pattern 13. These insulating resin coating layers 17 include a solder resist layer and a cover layer. The solder resist layer or cover layer as the insulating resin coating layer 17 has a predetermined thickness relative to the wiring pattern 13 to be protected. In the wiring board of the present invention, the thickness of the insulating resin coating layer 17 such as a solder resist or a cover layer is within the range of from 50 to 150%, preferably from 101 to 150%, more preferably from 105 to 140% relative to the thickness of the insulating board 11 such as a polyimide film.

When the thickness of the insulating resin coating layer formed on the surface of the wiring pattern 13 is within the above predetermined range relative to the thickness of the insulating board 11, it is possible to effectively prevent the breakage of the wiring pattern 13 at the folding portion 16 in the wiring board of the present invention. Such thickness of the insulating resin coating layer 17 does not adversely affect the excellent flexibility of the wiring board of the present invention. On the contrary, when the wiring pattern 13 formed from a conductive metal is folded for use in the folding portion 16, the insulating resin coating layer 17 compensates for the strength of the wiring pattern in the folding portion 16 to enable prevention of the breakage of the wiring pattern 13 in the folding portion 16.

Even if the constitutions (A), (B), (C) and (D) are adopted individually, the breakage of the wiring pattern 13 in the folding portion 16 can be prevented. However, adopting the constitutions in combination produces a far more superior effect than expected based on simple addition of effects by, the individual constitutions. Therefore, when the present invention is carried out, two or more of (A) to (D) above are preferably satisfied simultaneously, with examples including the combination of (A) and (B), the combination of (A) and (C), the combination of (A) and (D), the combination of (B) and (C), the combination of (B) and (D), and the combination of (C) and (D). Further, arbitrary three or more constitutions are preferably satisfied simultaneously. Furthermore, (A), (B), (C) and (D) are all satisfied simultaneously. As a result, the breakage of the wiring pattern in the folding portion 16 is extremely unlikely.

The printed wiring board of the present invention obtained in this manner has extremely high folding endurance. MIT test (conditions: solder resist portion 18: curvature radius 0.8 mm, curvature angle ±135°, curvature speed 175 rpm, load 100 gf/10 mm) is generally used for testing the folding endurance of wiring boards. Most conventional wiring boards without the constitutions of the invention have broken wires after less than 100 times of folding in the folding endurance test by MIT. In contrast, the wiring board according to the invention generally undergoes more than 120 times, and frequently more than 130 times of folding without broken wires. The wiring board capable of withstanding more than 120 times, preferably more than 130 times of folding in the MIT test can be installed in an electronic apparatus in a folded condition with semiconductor chips mounted on the wiring board, and can be used for an extended period without the wiring pattern 13 being broken by small but continuous stress.

The wiring board 10 of the present invention has the constitutions as described above. The copper layer for forming a wiring pattern and the insulating board as described above can be formed by an arbitrary method. For example, a copper layer may be formed on at least one surface of the insulating board by a metallizing method, casting method, laminating method or the like, thereby producing a substrate film.

A photosensitive resin is applied on the surface of the copper layer formed as described above and is cured at from 70 to 130° C. for from 1 to 10 minutes to give a photosensitive resin layer. The photosensitive resin layer is exposed to light through a desired mask, and the latent image is developed to produce a pattern of the cured resin. The pattern formed in this manner is used as a masking material and the copper layer is selectively etched to form a wiring pattern of copper.

After the wiring pattern is formed by this selective etching, the masking material (cured resin pattern) is removed by alkaline cleaning or the like.

A resin coating layer is formed on the wiring pattern such that the terminals will be exposed. Specifically, a solder resist may be applied at a temperature of from 100 to 180° C. and may be treated at this temperature for from 30 to 300 minutes. Thereafter, the terminals are plated and are treated at from 80 to 200° C. for from 20 to 180 minutes.

In the production of the wiring board as described above, the copper may be heated at near a recrystallization temperature of copper (normally from 200 to 250° C.), for example, in steps of laminating the electrodeposited copper foil and the polyimide film, casting and extending the polyimide precursor on a copper foil and heating the precursor for curing, and forming the solder resist layer on the wiring pattern. The characteristics of the copper particles as described above refer to the characteristics of copper that has been formed into a wiring pattern.

The wiring board of the present invention produced as described above shows very excellent folding endurance and is extremely resistant to breakage of the wiring pattern even when used in a folded condition for a long period of time.

A semiconductor chip may be bonded on the wiring board and may be sealed with a resin, thereby obtaining a semiconductor device. The wiring pattern in the semiconductor device shows excellent folding endurance. This semiconductor device may be folded and connected to, for example, a liquid crystal panel board.

### EXAMPLE

Next, the present invention will be described in detail by way of examples on a wiring board of the present invention; however, the invention is by no means limited thereto.

### Example 1

First, copper was deposited at a thickness of 12 μm on a drum-like electrode at a solution temperature of 50° C. at a current density of 60 A/dm² by means of a sulfuric acid-based copper electrolytic solution having a copper concentration of 80 g/liter, a free sulfuric acid concentration of 140 g/liter, a 1,3-mercapto-1-propanesulfonic acid concentration of 4 ppm, a diallyldimethylammonium chloride (Available from Senka Corp., Unisense FPA100L) concentration of 3 ppm and a chloride concentration of 10 ppm, thereby producing an electrodeposited copper foil. The M face of this electrodeposited copper foil was roughened by nodule plating treatment and coverplating treatment to adjust the surface roughness (Rz) of the M face to 1.5 μm.

A polyimide resin precursor was applied on the M face of this electrodeposited copper foil and the coating was heated at 350° C. for 60 minutes to give a polyimide film 38 μm in thickness. Consequently, a board film was produced which was a laminate of the electrodeposited copper foil with a thickness of 15 μm and the polyimide film with a thickness of 38 μm.

The entire surface of the electrodeposited copper foil of the board film was etched (half etched) to a copper thickness of 8 μm. A photosensitive resin layer was formed on the surface of the electrodeposited copper foil layer. Thereafter, this photosensitive resin layer was exposed to light and the latent image was developed to form a pattern.

The resultant pattern was used as a masking material and the electrodeposited copper foil layer was selectively etched by use of an etching solution to form a wiring pattern having leads 15 μm in width at a pitch width of 30 μm.

The masking material was removed by alkaline cleaning. A solder resist was applied such that inner leads and outer leads terminals were exposed, and the resist was cured by heating at 130° C. to form a solder resist layer with a thickness of 10 μm.

Furthermore, tin was deposited at a thickness of 0.45 μm on the surfaces of the inner and outer leads (terminals) exposed from the solder resist layer. The unit was allowed to stand at 120° C. for 2 hours, and a wiring board according to the present invention was obtained.

The wiring pattern formed as described above was analyzed with an electron back-scatter patterning apparatus (EBSP; INCA Crystal 300 available from OXFORD, INST). The mean crystal particle diameter was found to be 0.7 μm. Particles having a diameter of less than 1 μm accounted for 23% of the volume of the wiring pattern, and copper crystal particles that were [100] oriented in the longitudinal direction of the wiring pattern accounted for 16% of the volume of the wiring pattern. The wiring pattern included a number of wires extending parallel to the longitudinal direction of the board film. The EBSP proved that the copper crystal particles that were [100] oriented were parallel to this longitudinal direction.

The wiring board was folded at a central area of the solder resist layer with use of an MIT testing apparatus at a curvature radius of 0.8 mm, a curvature angle of ±135°, a curvature speed of 175 rpm and a load of 100 gf/10 mm. As a result, the wiring board endured 130 times of folding.

### Comparative Example 1

A board film was produced as in Example 1 except that the electrodeposited copper foil was replaced by a commercially available electrodeposited copper foil with a thickness of 12 μm (available from MITSUI MINING & SMELTING CO., LTD., VLP foil). A wiring board was produced using this board film in the same manner as in Example 1.

The wiring pattern formed was analyzed with EBSP. The mean crystal particle diameter was found to be 0.4 μm. Particles having a diameter of less than 1 μm accounted for 72% of the volume of the wiring pattern, and copper crystal particles that were [100] oriented in the longitudinal direction of the wiring pattern accounted for 9.4% of the volume of the wiring pattern.

The wiring board was tested with use of an MIT testing apparatus in the same manner as in Example 1. As a result, the wiring board endured 50 times of folding.

The results of Example 1 and Comparative Example 1 prove that the electrodeposited copper foil of Example 1 in which a specific amount of copper crystal particles were [100] oriented provided significantly improved folding endurance.

### Examples 2 and 3

A seed metal layer comprised of Cr and Ni was sputtered on a polyimide film having a tensile strength of 520 MPa, a Young's modulus of 9300 MPa and a thickness of 34.2 μm (Example 2) or 34.0 μm (Example 3). Copper was deposited on the surface of this seed metal layer by plating to produce a metal layer (Ni—Cr, Cu) at a thickness shown in Table 1, thereby producing a substrate film. A wiring board was produced as in Example 1 except that this substrate film was used. The polyimide film used herein comprised a polyimide obtained by use of biphenyltetracarboxylic dianhydride as a tetracarboxylic dianhydride component.

The wiring board was tested with use of an MIT testing apparatus in the same manner as in Example 1. The results are shown in Table 2.

### Comparative Examples 2 and 3

A substrate film was produced in the same manner as in Example 2 except that the polyimide film was replaced by a polyimide film having a tensile strength of 360 MPa, a Young's modulus of 5800 MPa and a thickness of 37.8 μm (Comparative Example 2) or 38.2 μm (Comparative Example 3). A wiring board was produced as in Example 1 except that this substrate film was used. The polyimide film used herein comprised a polyimide obtained by use of pyromellitic dianhydride as a tetracarboxylic dianhydride component.

The wiring board was tested with use of an MIT testing apparatus in the same manner as in Example 1. The results are shown in Table 2.

TABLE 2

| | | | Comparative | | Comparative |
|---|---|---|---|---|---|
| Sample | | Example 2 | Example 2 | Example 3 | Example 3 |
| Sample for | Substrate film fabrication | Metallizing | Metallizing | Metallizing | Metallizing |
| testing | method | method | method | method | method |
| Physical | Tensile strength of | 520 MPa | 360 MPa | 520 MPa | 360 MPa |
| properties of | insulating layer | | | | |
| insulating | Young's modulus of | 9300 MPa | 5800 MPa | 9300 MPa | 5800 MPa |
| layer | insulating layer | | | | |
| Wiring board | Wiring board thickness | 7.6 μm | 8.0 μm | 8.1 μm | 7.9 μm |
| for folding | Thickness of insulating | 34.2 μm | 37.8 μm | 34.0 μm | 38.2 μm |
| endurance | layer (μm) | | | | |
| testing | Solder resist thickness (μm) | 8.7 μm | 9.7 μm | 9.2 μm | 8.1 μm |
| | Wiringpitch (line and space) | 30 μm | 30 μm | 30 μm | 30 μm |
| | width (μm) | | | | |
| | Lead bottom width (μm) | 11.3 μm | 16.2 μm | 13.0 μm | 14.0 μm |
| Folding | Load | 100 gf/10 mm | 100 gf/10 mm | 100 gf/10 mm | 100 gf/10 mm |
| endurance | Folding position | Solder | Solder | Solder | Solder |
| evaluation | | resist | resist | resist | resist |
| conditions | | portion | portion | portion | portion |
| | Folding radius R (mm) | 0.8 mm | 0.8 mm | 0.8 mm | 0.8 mm |
| Folding | Folding endurance | 191 | 104 | 184 | 114 |
| endurance | (Number of times of folding) | | | | |
| test result | | | | | |

Table 2 above shows that the wiring boards display increased folding endurance by use of insulating polyimide films having a tensile strength within the range of from 450 to 600 MPa and a Young's modulus within the range of from 8500 to 9500 MPa.

### Example 4 and Comparative Example 4

A commercially available electrodeposited copper foil having a thickness of 15 μm (available from MITSUI MINING & SMELTING CO., LTD., VLP foil) and a polyimide film having a tensile strength of 380MPa, a Young's modulus of 5800 MPa and a thickness of 25 μm (Example 4) or 38 μm (Comparative Example 4) were laminated to produce a substrate film. A wiring board was produced as in Example 1 except that this substrate film was used. The polyimide film used herein comprised a polyimide obtained by use of pyromellitic dianhydride as a tetracarboxylic dianhydride component.

The wiring board was tested with use of an MIT testing apparatus in the same manner as in Example 1. The results are shown in Table 3.

TABLE 3

| | | Sample | |
|---|---|---|---|
| | | | Comparative |
| | | Example 4 | Example 4 |
| Sample for | substrate film | Laminating | Laminating |
| testing | fabrication | method | method |
| | method | | |
| Physical | Tensile | 360 MPa | 360 MPa |
| properties of | strength of | | |
| insulating | insulating | | |
| layer | layer | | |
| | Young's modulus | 5800 MPa | 5800 MPa |
| | of insulating | | |
| | layer | | |
| Wiring board | Wiring board | 8.0 μm | 8.0 μm |
| for folding | thickness (μm) | | |
| endurance | Thickness of | 25.0 μm | 38.0 μm |
| testing | insulating | | |
| | layer (μm) | | |
| | Solder resist | 10.2 μm | 9.7 μm |
| | thickness (μm) | | |
| | Wiring pitch | 30 μm | 30 μm |
| | (line and space) | | |
| | width (μm) | | |
| | Lead bottom | 16.2 μm | 15.7 μm |
| | width (μm) | | |
| Folding | Load | 100 gf/10 mm | 100 gf/10 mm |
| endurance | Folding | Solder resist | Solder resist |
| evaluation | position | portion | portion |
| conditions | Folding radius R | 0.8 mm | 0.8 mm |
| | (mm) | | |
| Folding | Folding | 621 | 105 |
| endurance test | endurance | | |
| result | (number of times | | |
| | of folding) | | |

Table 3 above shows that the folding endurance of the wiring pattern of the wiring board is remarkably improved by use of insulating polyimide films having a thickness of from 10 to 30 μm, preferably from 22 to 28 μm.

### Example 5

A seed metal layer comprised of Cr and Ni was sputtered on a polyimide film having a tensile strength of 520 MPa, a Young's modulus of 9300 MPa and a thickness of 34.2 μm. Copper was deposited on the surface of this seed metal layer by plating to produce a metal layer (Ni—Cr, Cu) at a thickness of 7.6 μm as shown in Table 3, thereby producing a board film. A wiring pattern was produced as in Example 1 except that this substrate film was used. The polyimide film used herein comprised a polyimide obtained by use of biphenyltetracarboxylic dianhydride as a tetracarboxylic dianhydride component.

The thickness of the wiring pattern was 7.6 μm, and a solder resist layer was formed at a thickness of 37.5 μm. The thickness of the solder resist layer (37.5 μm) was 110% relative to the thickness of the polyimide film (34.2 μm).

The wiring board was tested with use of an MIT testing apparatus in the same manner as in Example 1. The results are shown in Table 4.

### Comparative Example 5

A seed metal layer comprised of Cr and Ni was sputtered on a polyimide film having a tensile strength of 360 MPa, a Young's modulus of 5800 MPa and a thickness of 37.8 μm. Copper was deposited on the surface of this seed metal layer by plating to produce a metal layer (Ni—Cr, Cu) at a thickness of 8.0 μm as shown in Table 3, thereby producing a substrate film. A wiring pattern was produced as in Example 1 except that this board film was used. The polyimide film used herein comprised a polyimide obtained by use of pyromellitic dianhydride as a tetracarboxylic dianhydride component.

A solder resist layer having a thickness of 9.7 μm was formed on the wiring pattern such that inner leads and outer leads were exposed. The thickness of the solder resist layer (9.7 μm) was 26% relative to the thickness of the polyimide film (37.8 μm).

The wiring board was tested with use of an MIT testing apparatus in the same manner as in Example 1. The results are shown in Table 4.

TABLE 4

| | | Sample | |
|---|---|---|---|
| | | | Comparative |
| | | Example 5 | Example 5 |
| Sample for | Substrate film | Metallizing | Metallizing |
| testing | fabrication | method | method |
| | method | | |
| Physical | Tensile strength | 520 MPa | 360 MPa |
| properties of | of insulating | | |
| insulating | layer | | |
| layer | Young's modulus of | 9300 MPa | 5800 MPa |
| | insulating layer | | |
| Wiring board | Wiring board | 7.6 μm | 8.0 μm |
| for folding | thickness (μm) | | |
| endurance | Thickness of | 34.2 μm | 37.8 μm |
| testing | insulating layer | | |
| | (μm) | | |
| | Solder resist | 35 μm | 9.7 μm |
| | thickness (μm) | | |
| | Wiring pitch (line | 30 μm | 30 μm |
| | and space) width | | |
| | (μm) | | |
| | Lead bottom width | 11.3 μm | 16.2 μm |
| | (μm) | | |
| Folding | Load | 100 gf/10 mm | 100 gf/10 mm |
| endurance | Folding position | Solder | Solder |
| evaluation | | resist | resist |
| conditions | | portion | portion |
| | Folding radius R | 0.8 mm | 0.8 mm |
| | (mm) | | |
| Folding | Folding endurance | 204 | 104 |
| endurance test | (number of times of | | |
| result | folding) | | |

As shown in Table 4, the wiring boards display superior folding endurance when solder resist layers are formed at a thickness in the range of from 50 to 150%, preferably from 101 to 150%, relative to the thickness of the insulating film.

### Examples 6 to 10

A wiring board according to the present invention was produced as shown in Table 5 below. Examples 6 and 10 used the same electrodeposited copper foil as used in Example 1.

The wiring board was tested with use of an MIT testing apparatus in the same manner as in Example 1. The results are shown in Table 5. For reference, Table 5 also shows the constitution and test results of the wiring board produced in Comparative Example 2

TABLE 5

| | | Comparative | | | | | |
|---|---|---|---|---|---|---|---|
| Sample | | Example 2 | Example 6 | Example 7 | Example 8 | Example 9 | Example 10 |
| Sample for | Substrate film | Metallizing | Laminating | Metallizing | Metallizing | Metallizing | Laminating |
| testing | fabrication | method 1 | method | method 1 | method 1 | method 1 | method |
| | method | | | | | | |
| Physical | Tensile strength | 360 MPa | 360 MPa | 520 MPa | 520 MPa | 520 MPa | 520 MPa |
| properties | of insulating | | | | | | |
| of | layer | | | | | | |
| insulating | Young's modulus | 5800 MPa | 5800 MPa | 9300 MPa | 9300 MPa | 9300 MPa | 9300 MPa |
| layer | of insulating | | | | | | |
| | layer | | | | | | |
| Wiring | Wiring board | 8.0 μm | 8.1 μm | 7.9 μm | 7.9 μm | 7.9 μm | 8.1 μm |
| board for | thickness (μm) | | | | | | |
| folding | Thickness of | 37.8 μm | 25 μm | 38.2 μm | 25 μm | 25 μm | 25 μm |
| endurance | insulating layer | | | | | | |
| testing | (μm) | | | | | | |
| | Solder resist | 9.7 μm | 9.2 μm | 35 μm | 9.4 μm | 35 μm | 35 μm |
| | thickness (μm) | | | | | | |
| | Wiring pitch | 30 μm | 30 μm | 30 μm | 30 μm | 30 μm | 30 μm |
| | (line and space) | | | | | | |
| | width (μm) | | | | | | |
| | Lead bottom width | 16.2 μm | 13 μm | 14 μm | 14 μm | 14 μm | 13 μm |
| | (μm) | | | | | | |
| Folding | Load | 100 gf/10 mm | | | | | |
| endurance | Folding position | Solder resist portion | | | | | |
| evaluation | Folding radius R | 0.8 | 0.8 | 0.8 | 0.8 | 0.8 | 0.8 |
| conditions | (mm) | | | | | | |
| Folding | Folding | 105 | 351 | 138 | 451 | 480 | 597 |
| endurance | endurance | | | | | | |
| test result | (number of times | | | | | | |
| | of folding) | | | | | | |

As described above, combining the constitutions specified in the present invention provides wiring boards having higher folding endurance.

The wiring boards according to the present invention have the constitutions (A) to (D) as described above and consequently have excellent folding endurance. The wiring boards of the invention can be folded for use without breakage of the wiring patterns.

1. A wiring board excellent in folding endurance in which a copper-containing wiring pattern is formed on at least one face of an insulating film and in which an insulating resin coating layer is formed on the wiring pattern such that terminals of the wiring pattern are exposed, wherein the wiring board has at least one constitution selected from the group consisting of (A), (B), (C) and (D) below:
(A) the wiring pattern comprises copper particles having a mean crystal particle diameter in the range of from 0.65 to 0.85 μm as determined by means of an electron back-scatter patterning (EBSP) analyzer; not more than 1% of the volume of the wiring pattern is accounted for by copper crystal particles having a particle diameter of less than 1.0 μm as determined by EBSP; and copper crystal particles that are [100] oriented in the longitudinal direction of a lead of the wiring pattern account for from 10 to 20% of the volume of the wiring pattern as determined by EBSP;
(B) the insulating film is formed of a polyimide film having a tensile strength within the range of from 450 to 600 MPa and a Young's modulus within the range of from 8500 to 9500 MPa;
(C) the insulating film is formed of a polyimide film having a thickness of from 10 to 30 μm; and
(D) the insulating resin coating layer formed on the wiring pattern has a thickness of from 50 to 150% relative to the thickness of the insulating film.

2. The wiring board according to claim 1, wherein the wiring board is used by being folded at a curvature radius of from 0.1 to 5.0 mm and at 90 to 180°.

3. The wiring board according to claim 1, wherein not less than 95% in number of the copper crystal particles in the wiring pattern have a particle diameter of not more than 3 μm.

4. The wiring board according to claim 1, wherein the insulating film comprises a polyimide formed with use of biphenyltetracarboxylic dianhydride as a tetracarboxylic dianhydride component.

5. The wiring board according to claim 1, wherein in the constitution (D), the insulating resin coating layer formed on the wiring pattern has a thickness of from 101 to 150% relative to the thickness of the insulating film.

6. The wiring board according to claim 1, wherein the wiring pattern has inner leads at a pitch width of not more than 35 μm.

7. A semiconductor device comprising the wiring board of claim 1 and an electronic part mounted on the wiring board.

8. A semiconductor device comprising the wiring board of claim 2 and an electronic part mounted on the wiring board.

9. A semiconductor device comprising the wiring board of claim 3 and an electronic part mounted on the wiring board.

10. A semiconductor device comprising the wiring board of claim 4 and an electronic part mounted on the wiring board.

11. A semiconductor device comprising the wiring board of claim 5 and an electronic part mounted on the wiring board.

12. A semiconductor device comprising the wiring board of claim 6 and an electronic part mounted on the wiring board.
